(19) United States
(12) Patent Application Publication
(10) Pub. No.: US 2026/0118892 A1
(43) Pub. Date: Apr. 30, 2026

(54) Transport Facility

(71) Applicant: Daifuku Co., Ltd., Osaka-shi (JP)

(72) Inventors: Shota Ito, Komaki-shi (JP); Yuki Okahashi, Komaki-shi (JP)

(21) Appl. No.: 19/369,486

(22) Filed: Oct. 27, 2025

(30) Foreign Application Priority Data
Oct. 28, 2024 (JP) 2024-188840

(51) Int. Cl. G05D 1/698; B61L 27/10; G05D 101/15; G05D 105/20

(52) U.S. Cl. CPC G05D 1/6987; B61L 27/10; G05D 2101/15; G05D 2105/20

(57) ABSTRACT

A transport facility includes a predefined travelable path, a plurality of transport vehicles, and a control system. The control system includes a state information obtainer that obtains state information indicating a positional relationship among the plurality of transport vehicles in a control area, an evaluation processor that outputs an evaluation value for each of a plurality of travel patterns based on state information and an evaluation criterion, and a traffic controller that performs traffic control of the plurality of transport vehicles in the control area based on a travel pattern having a highest evaluation value among the plurality of travel patterns. The evaluation criterion is defined to allow, based on learning results, a higher evaluation value for a less average of travel time periods of all the plurality of transport vehicles in the control area.

### CROSS-REFERENCE TO RELATED APPLICATION

This application claims priority to Japanese Patent Application No. 2024-188840 filed Oct. 28, 2024, the disclosure of which is hereby incorporated by reference in its entirety.

### BACKGROUND OF THE INVENTION

### Field of the Invention

The present invention relates to a transport facility.

### Description of Related Art

Transport facilities including a predefined travelable path, multiple transport vehicles that travel along the travelable path, and a control system that controls the transport vehicles are available. An example of such a transport facility is described in Japanese Unexamined Patent Application Publication No. 2006-313463.

In an article transport facility described in Japanese Unexamined Patent Application Publication No. 2006-313463, a transport vehicle (carriage 5) approaching a junction (an intersection with a shortcut 3) on a travelable path (travel rail 1) transmits a blocking request to a control system (zone controller 11). The control system receiving the blocking request determines whether the transport vehicle can enter the junction, and returns a permission signal to the transport vehicle when permitting the entry. Such an entry adjustment process prevents collisions between transport vehicles at junctions.

Japanese Unexamined Patent Application Publication No. 2006-313463 describes a technique for preventing collisions between transport vehicles to avoid a large decrease in transport efficiency. However, the technique cannot increase the overall transport efficiency of multiple transport vehicles in areas including a junction.

### SUMMARY OF THE INVENTION

In view of the foregoing, the overall transport efficiency of multiple transport vehicles is thus to be increased when traveling in areas including at least one junction in the transport facility.

A transport facility according to an aspect of the disclosure includes a predefined travelable path, a plurality of transport vehicles that travel along the travelable path, and a control system that controls the plurality of transport vehicles. The travelable path includes at least one junction at which a plurality of paths merge. The control system includes a state information obtainer, an evaluation processor, and a traffic controller. The state information obtainer obtains, when the plurality of transport vehicles are in a control area including the at least one junction, state information including information indicating a positional relationship among the plurality of transport vehicles in the control area. The evaluation processor defines a plurality of travel patterns based on combinations of permission and prohibition for each of the plurality of transport vehicles to travel on each of the plurality of paths connected to the at least one junction in the control area, and outputs, using the state information as input, an evaluation value for each of the plurality of travel patterns based on an evaluation criterion obtained through learning. The traffic controller performs traffic control of the plurality of transport vehicles in the control area based on a travel pattern having a highest evaluation value among the plurality of travel patterns. The evaluation criterion is defined to allow, based on results of learning a relationship among the state information, the travel pattern, and a travel time period in a past, a higher evaluation value for a less average of travel time periods of all the plurality of transport vehicles in the control area. The travel time period is a time period taken by a corresponding transport vehicle of the plurality of transport vehicles to pass the at least one junction after entering the control area.

In this structure, the evaluation criterion obtained through learning is defined to allow, a higher evaluation value for a less average of travel time periods of all the transport vehicles in the control area including at least one junction. Using such an evaluation criterion, an evaluation value for each of the possible travel patterns is output to perform traffic control based on the travel pattern having the highest evaluation value. This increases the transport efficiency of all the transport vehicles traveling in the area including at least one junction.

Further features and advantages of the technique according to the present disclosure will be apparent from exemplary and nonlimiting embodiments described below with reference to the drawings.

### BRIEF DESCRIPTION OF THE DRAWINGS

FIG. 1 is a schematic diagram of a transport facility according to an embodiment.

FIG. 2 is a block diagram of a control system.

FIG. 3 is a model diagram of state information obtained as states of multiple transport vehicles in a control area.

FIG. 4 is a schematic diagram of paths travelable for the respective transport vehicles at junctions.

FIG. 5 is a schematic diagram of travel patterns allowed at the junctions.

FIG. 6 is a model diagram describing input of base data used to calculate an evaluation value.

FIG. 7 is a diagram of example base data that is input to calculate the evaluation value.

### DESCRIPTION OF THE INVENTION

A transport facility according to an embodiment will be described with reference to the drawings.

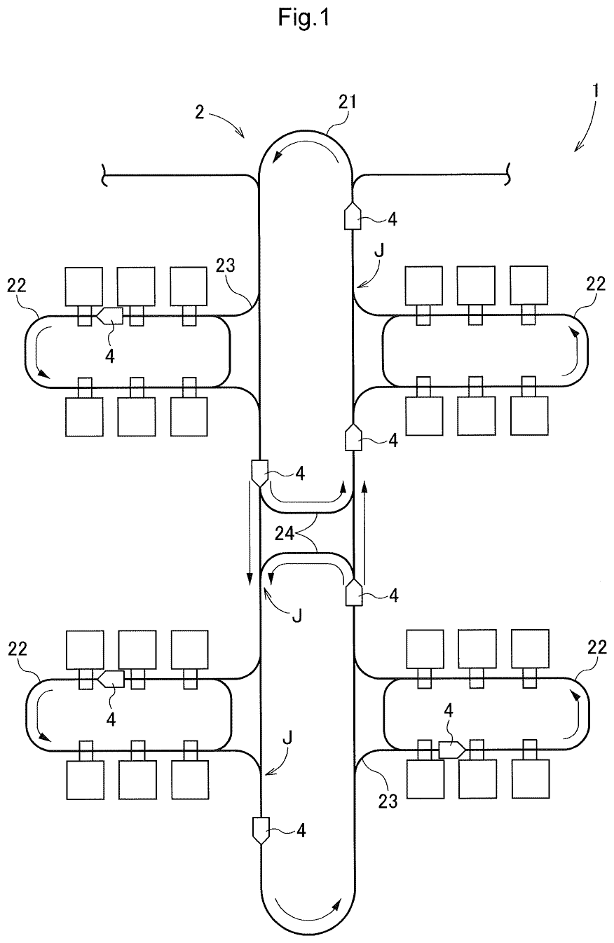

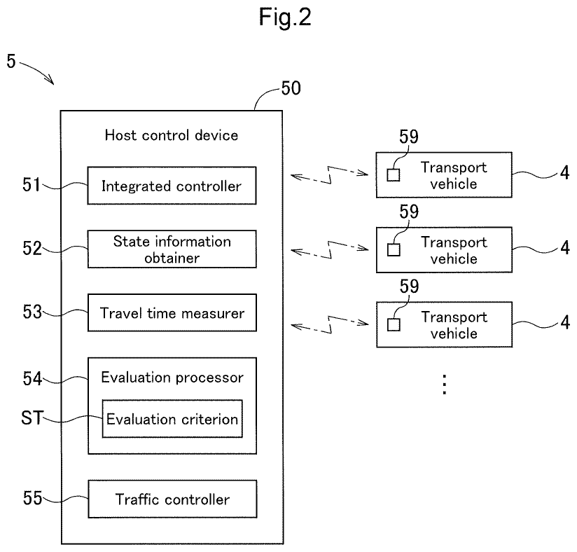

As shown in FIGS. 1 and 2, a transport facility 1 includes a predefined travelable path 2, multiple transport vehicles 4 that travel along the travelable path 2, and a control system 5 that controls the transport vehicles 4.

The transport vehicles 4 transport articles. Each transport vehicle 4 travels along the travelable path 2 to transport an article. The transport vehicles 4 can be, for example, ceiling-hung transport vehicles. Each transport vehicle 4 travels along the travelable path 2 to transport the article based on a command from the control system 5.

The articles handled in the transport facility 1 and transported by the transport vehicles 4 include various items. For the transport facility 1 used in a semiconductor manufacturing plant, for example, the articles are wafer containers (front opening unified pods, or FOUPs) containing wafers or reticle containers (reticle pods) containing reticles. In this case, the transport vehicles 4 transport, between processes, the articles such as the wafer containers or the reticle containers along the travelable path 2.

The travelable path 2 is predefined in a predetermined shape. The travelable path 2 in the present embodiment includes a primary transport path 21 in the form of a loop and multiple secondary transport paths 22 each in the form of a smaller loop than the primary transport path 21. Each secondary transport path 22 is connected to the primary transport path 21 with connecting paths 23. The travelable path 2 in the present embodiment includes shortcuts 24 to provide shortcuts in the primary transport path 21, which is in the form of a relatively large loop. In the present embodiment, each of the primary transport path 21, the secondary transport paths 22, the connecting paths 23, and the shortcuts 24 corresponds to a path.

Each connecting path 23 branches from the primary transport path 21 and merges into the corresponding secondary transport path 22, or branches from the corresponding secondary transport path 22 and merges into the primary transport path 21. Each shortcut 24 branches from one point on the primary transport path 21 and merges into another point on the primary transport path 21. As described above, the travelable path 2 includes junctions J at which multiple paths merge. In this example, a merging point between the primary transport path 21 or the secondary transport path 22 and the corresponding connecting path 23 or a merging point between the primary transport path 21 and the corresponding shortcut 24 corresponds to a junction J.

For the transport vehicles 4 being the ceiling-hung transport vehicles, the travelable path 2 may be defined by rails hung from the ceiling.

The control system 5 controls the multiple transport vehicles 4. As shown in FIG. 2, the control system 5 in the present embodiment includes a host control device 50 and terminal control devices 59 that are mounted on the respective transport vehicles 4 to allow communication with the host control device 50. The control system 5 also includes an integrated controller 51, a state information obtainer 52, a travel time measurer 53, an evaluation processor 54, and a traffic controller 55. In the present embodiment, the integrated controller 51, the state information obtainer 52, the travel time measurer 53, the evaluation processor 54, and the traffic controller 55 are included in the host control device 50.

The integrated controller 51 substantially controls the multiple transport vehicles 4 in the entire transport facility 1.

When an article is to be transported to a destination, the integrated controller 51 performs control to deploy an unloaded transport vehicle 4 to a starting point, cause the transport vehicle 4 to receive the article, and deploy the loaded transport vehicle 4 to the destination. The integrated controller 51 performs these control operations for each article to be transported. The integrated controller 51 tracks the position of each transport vehicle 4.

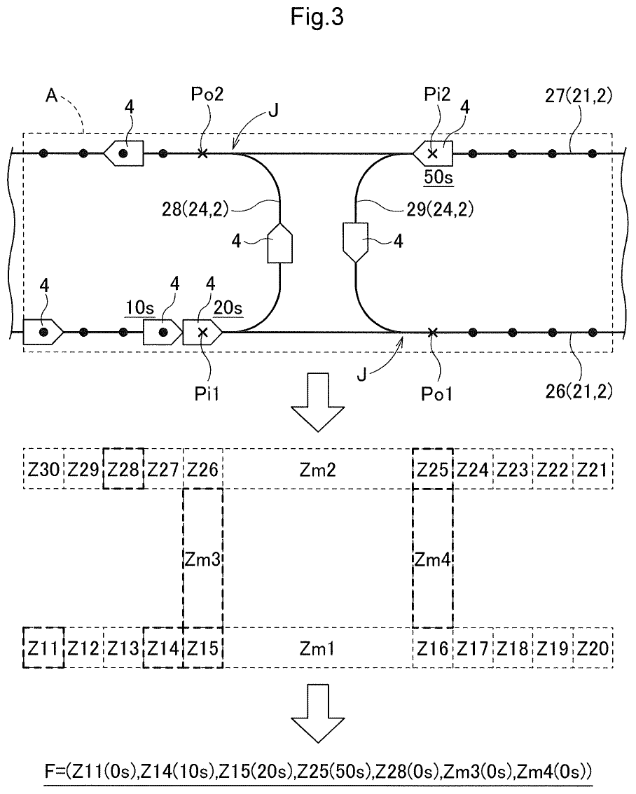

The state information obtainer 52 obtains state information F including information indicating the positional relationship among the transport vehicles 4 in a control area A including at least one junction J. The control area A includes, for example, at least one junction J and is defined within predetermined distances upstream and downstream from each junction J. In one example, the upper part of FIG. 3 shows the control area A defined near the junctions J between the primary transport path 21 and the shortcuts 24.
In this example, two shortcuts 24 connect the middle portion of the primary transport path 21.

In the example in FIG. 3, the primary transport path 21 includes a first straight rail 26 and a second straight rail 27 arranged parallel to each other in opposite directions. The two shortcuts 24 include a first connecting rail 28 and a second connecting rail 29 that are curved in the form of an arc, face each other, and are connected to the first straight rail 26 and the second straight rail 27. A first entry position Pi1 is upstream from a branch between the first straight rail 26 and the first connecting rail 28, and a second entry position Pi2 is upstream from a branch between the second straight rail 27 and the second connecting rail 29. A first exit position Po1 is downstream from a junction J between the first straight rail 26 and the second connecting rail 29, and a second exit position Po2 is downstream from a junction J between the second straight rail 27 and the first connecting rail 28.

The control area A includes a portion on the first straight rail 26 including a point at a predetermined distance upstream from the first entry position Pi1 to a point at a predetermined distance downstream from the first exit position Po1, a portion on the second straight rail 27 including a point at a predetermined distance upstream from the second entry position Pi2 to a point at a predetermined distance downstream from the second exit position Po2, the first connecting rail 28, and the second connecting rail 29. The predetermined distances in this case may be, for example, any distances within the range of 3 to 10 m.

When a single transport vehicle 4 is in the control area A, the state information F obtained by the state information obtainer 52 includes the positional information of the transport vehicle 4 in the control area A. When multiple transport vehicles 4 are in the control area A, the state information F obtained by the state information obtainer 52 includes the information indicating the positional relationship (a combination of positions) among the transport vehicles 4 in the control area A.

The state information obtainer 52 tracks the positions of the transport vehicles 4 in the control area A by modeling as shown in the lower part of FIG. 3. More specifically, the state information obtainer 52 divides a portion on the first straight rail 26 upstream from the first entry position Pi1 into regular intervals to track the portion as positions Z11, Z12, Z13, Z14, and Z15. The state information obtainer 52 tracks a portion between the first entry position Pi1 and the first exit position Po1 on the first straight rail 26 as a position Zm1. The state information obtainer 52 also divides a portion on the first straight rail 26 downstream from the first exit position Po1 into regular intervals to track the portion as positions Z16, Z17, Z18, Z19, and Z20. The position Z15 corresponds to the first entry position Pi1, and the position Z16 corresponds to the first exit position Po1.

The state information obtainer 52 also divides a portion on the second straight rail 27 upstream from the second entry position Pi2 into regular intervals to track the portion as positions Z21, Z22, Z23, Z24, and Z25. The state information obtainer 52 also tracks a portion between the second entry position Pi2 and the second exit position Po2 on the second straight rail 27 as a position Zm2. The state information obtainer 52 also divides a portion on the second straight rail 27 downstream from the second exit position Po2 into regular intervals to track the portion as positions Z26, Z27, Z28, Z29, and Z30. The position Z25 corresponds to the second entry position Pi2, and the position Z26 corresponds to the second exit position Po2. The state information obtainer 52 also tracks the first connecting rail 28 as a position Zm3 and the second connecting rail 29 as a position Zm4.

In the example in FIG. 3, the control area A includes multiple transport vehicles 4 as shown in the upper part. In this case, the state information obtainer 52 obtains the state information F including information about a combination of positions of the transport vehicles 4. More specifically, the state information F obtained in this case is (Z11, Z14, Z15, Z25, Z28, Zm3, and Zm4).

The state information F may simply include the positional information of each transport vehicle 4, or may also include information indicating a degree of waiting time periods for each transport vehicle 4 in the control area A. The information indicating the degree of waiting time periods may be the actual length of the waiting time up to the time point (in other words, stop duration at a specific position) or may be a classified length of the waiting time. In this example, the state information F includes the positional information of each transport vehicle 4 and the information indicating the actual length of the waiting time for each transport vehicle 4. In the example shown in the upper part of FIG. 3, some of the transport vehicles 4 have been waiting for the displayed amount of time. The state information F obtained in this case is (Z11 (0 s), Z14 (10 s), Z15 (20 s), Z25 (50 s), Z28 (0 s), Zm3 (0 s), and Zm4 (0 s)).

In the present embodiment, the state information F includes travel direction information about each transport vehicle 4. The travel direction information in this example refers to information about a planned path to be traveled by a transport vehicle 4. More specifically, the travel direction information includes information indicating whether a transport vehicle 4 that has traveled on the first straight rail 26 and reached the first entry position Pi1 is to travel straight on the first straight rail 26 or to change the travel path onto the first connecting rail 28. The travel direction information also includes information indicating whether a transport vehicle 4 that has traveled on the second straight rail 27 and reached the second entry position Pi2 is to travel straight on the second straight rail 27 or to change the travel path onto the second connecting rail 29.

The information about the waiting time for each transport vehicle 4 may be obtained as control information tracked by the integrated controller 51 or as information measured on each transport vehicle 4 in the control area A. The travel direction information about each transport vehicle 4 is also obtained as, for example, the control information tracked by the integrated controller 51.

The state information obtainer 52 obtains the state information F in a predetermined cycle (e.g., in a cycle of once per second).

The travel time measurer 53 measures a travel time taken by a transport vehicle 4 to pass a junction J after entering the control area A. In the present embodiment, the travel time measurer 53 measures the travel time for each transport vehicle 4 based on the positional information of each transport vehicle 4 tracked by the integrated controller 51.

The evaluation processor 54 outputs, using the state information F obtained by the state information obtainer 52 as input, an evaluation value for each of multiple travel patterns based on an evaluation criterion ST obtained through learning. The multiple travel patterns are defined based on combinations of results of determining whether each transport vehicle 4 is permitted to travel on each of the multiple paths connected to the junctions J in the control area A.

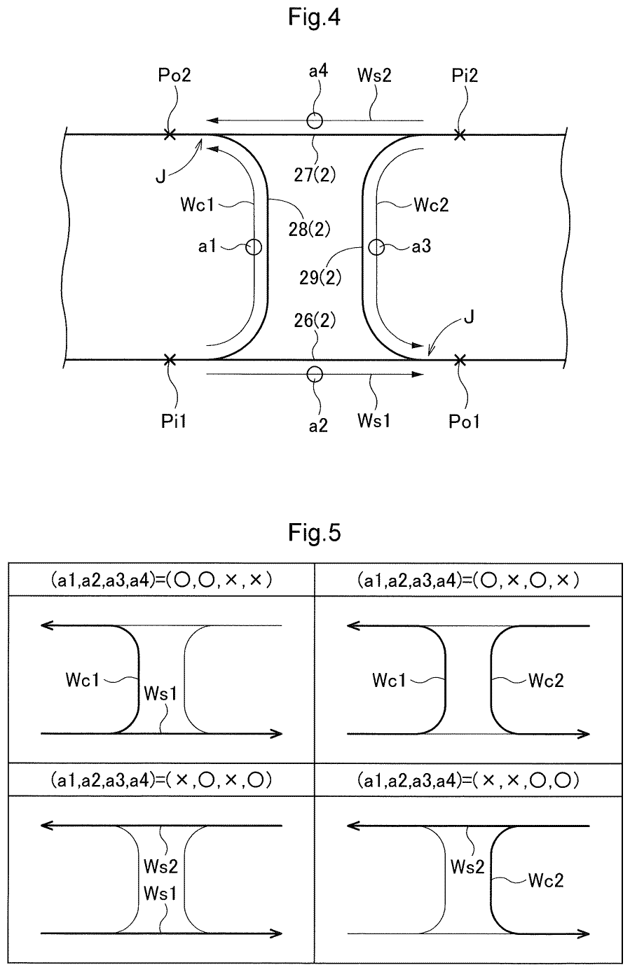

FIG. 4 shows multiple routes on which the transport vehicles 4 may travel in the control area A shown in FIG. 3. As shown in this figure, the transport vehicles 4 in the control area A may travel on a first straight route Ws1, a second straight route Ws2, a first curved route Wc1, or a second curved route Wc2. The first straight route Ws1 is a route for a transport vehicle 4 that has traveled on the first straight rail 26 and continues to travel straight on the first straight rail 26. The second straight route Ws2 is a route for a transport vehicle 4 that has traveled on the second straight rail 27 and continues to travel straight on the second straight rail 27. The first curved route Wc1 is a route for a transport vehicle 4 that has traveled on the first straight rail 26, and branches from the first straight rail 26 to allow the transport vehicle 4 to travel along curves on the first connecting rail 28 and joins the second straight rail 27. The second curved route Wc2 is the route for a transport vehicle 4 that has traveled on the second straight rail 27, and branches from the second straight rail 27 to allow the transport vehicle 4 to travel along curves on the second connecting rail 29 and joins the first straight rail 26.

In the present embodiment, a1 indicates whether the first connecting rail 28 is travelable, and a2 indicates whether the portion between the first entry position Pi1 and the first exit position Po1 on the first straight rail 26 is travelable. Further, a3 indicates whether the second connecting rail 29 is travelable, and a4 indicates whether the portion between the second entry position Pi2 and the second exit position Po2 on the second straight rail 27 is travelable. The travelability a1, a2, a3, and a4 each indicate whether travel is permitted or prohibited.

When travel on the first connecting rail 28 is permitted (a1: permitted), the transport vehicle 4 can travel along the first curved route Wc1. When travel through the portion downstream from the first entry position Pi1 on the first straight rail 26 is permitted (a2: permitted), the transport vehicle 4 can travel along the first straight route Ws1. When travel on the second connecting rail 29 is permitted (a3: permitted), the transport vehicle 4 can travel along the second curved route Wc2. When travel through the portion downstream from the second entry position Pi2 on the second straight rail 27 is permitted (a4: permitted), the transport vehicle 4 can travel along the second straight route Ws2.

In the present embodiment, out of a total of 16 combinations of travelability including the four portions, seven combinations that may cause collision at one of the junctions J and five combinations that decrease the transport efficiency with too many travel prohibition are excluded, resulting in four combinations used as the travel patterns for which evaluation values are output. More specifically, as shown in FIG. 5, the travel patterns for which evaluation values are output include a first travel pattern that permits a1 and a2 and prohibits others, a second travel pattern that permits a1 and a3 and prohibits others, a third travel pattern that permits a2 and a4 and prohibits others, and a fourth travel pattern that permits a3 and a4 and prohibits others.

In the first travel pattern, the multiple transport vehicles 4 in the control area A can travel on the first curved route Wc1 or the first straight route Ws1. In the second travel pattern, the multiple transport vehicles 4 in the control area A can travel on the first curved route Wc1 or the second curved route Wc2. In the third travel pattern, the multiple transport vehicles 4 in the control area A can travel on the first straight route Ws1 or the second straight route Ws2. In the fourth travel pattern, the multiple transport vehicles 4 in the control area A can travel on the second curved route Wc2 or the second straight route Ws2.

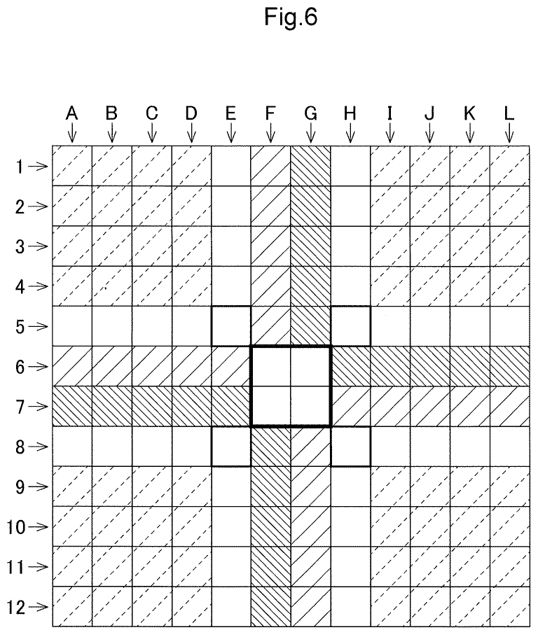

As described above, the evaluation processor 54 outputs, using the state information F as input, an evaluation value for each of the multiple travel patterns based on the evaluation criterion ST obtained through learning. FIG. 6 is a model diagram describing input of the base data used by the evaluation processor 54 to calculate an evaluation value.

In the model diagram including 12 rows and 12 columns (cells A1 to L12), the cells indicate different positions in the control area A as described below.
Cells A6 to E6: the positions Z11 to Z15 in the first curved route Wc1
Cells F5 to F1: the positions Z26 to Z30 in the first curved route Wc1
Cells A7 to E7: the positions Z11 to Z15 in the first straight route Ws1
Cells F8 to F12: the positions Z16 to Z20 in the first straight route Ws1
Cells L7 to H7: the positions Z21 to Z25 in the second curved route Wc2
Cells G8 to G12: the positions Z16 to Z20 in the second curved route Wc2
Cells L6 to H6: the positions Z21 to Z25 in the second straight route Ws2
Cells G5 to G1: the positions Z26 to Z30 in the second straight route Ws2
Cells A1 to D4: the position Zm3
Cells A12 to D9: the position Zm1
Cells L12 to 19: the position Zm4
Cells L1 to 14: the position Zm2

Based on the obtained state information F, a value is input into each of the above cells following the rules described below.

### Default: 0

Transport vehicle 4 at the corresponding position: +0.5
Waiting time: +f (waiting time), where 0<f (waiting time)≤0.5

Information is input into each cell as described below.
Cell E5: the travelability a1 at the time point
Cell E8: the travelability a2 at the time point
Cell H8: the travelability a3 at the time point
Cell H5: the travelability a4 at the time point
Cell F6: the travelability a1 of the travel pattern to be evaluated
Cell F7: the travelability a2 of the travel pattern to be evaluated
Cell G7: the travelability a3 of the travel pattern to be evaluated
Cell G6: the travelability a4 of the travel pattern to be evaluated

More specifically, a value is input into each of the above cells following the rules described below.
The travelability a1 to a4 indicating travel being permitted: 0.8
The travelability a1 to a4 indicating travel being prohibited: 0.2

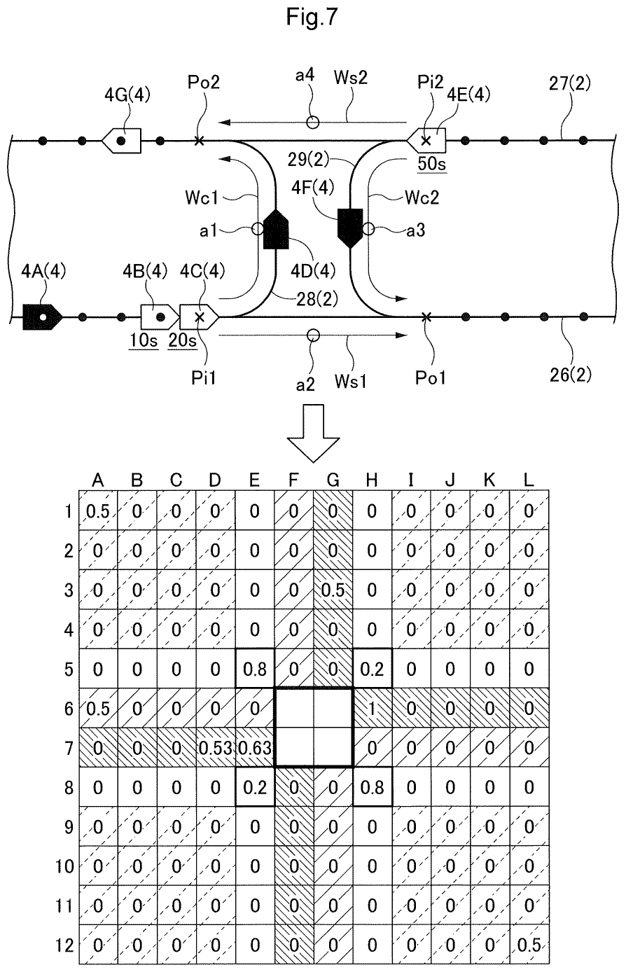

FIG. 7 more specifically describes the base data that is input to calculate the evaluation value with reference to the example positions in FIG. 3. In FIG. 7, the transport vehicles 4 are denoted with reference numerals 4A to 4G to distinguish them. In addition, the transport vehicles 4 traveling on the first straight route Ws1 or the second straight route Ws2 are indicated as outlined icons, and the transport vehicles 4 traveling on the first curved route Wc1 or the second curved route Wc2 are indicated as solid icons.

In this example, travel on the first connecting rail 28 and the second connecting rail 29 is permitted at the time point. In other words, the travelability a1 and a3 indicate that travel is permitted, and the travelability a2 and a4 indicate that travel is prohibited. Thus, the cells E5 and H8 respectively corresponding to the travelability a1 and a3 receive an input value of 0.8, and the cells E8 and H5 respectively corresponding to the travelability a2 and a4 receive an input value of 0.2.

The transport vehicle 4A is a transport vehicle 4 to travel on the first curved route Wc1 and is at the position Z11 on the first straight rail 26. The transport vehicle 4A has no waiting time at the time point. Thus, the cell A6 corresponding to the position Z11 of the transport vehicle 4A traveling on the first curved route Wc1 receives an input value of 0.5.

The transport vehicles 4B and 4C are transport vehicles 4 to travel on the first straight route Ws1 and are at the respective positions Z14 and Z15 on the first straight rail 26. The transport vehicle 4B has a waiting time of 10 seconds, and the transport vehicle 4C has a waiting time of 20 seconds at the time point. In this example, a value of 0.03 is added for the waiting time of 10 seconds, and a value of 0.13 is added for the waiting time of 20 seconds. Thus, the cell D7 corresponding to the position Z14 of the transport vehicle 4B traveling on the first straight route Ws1 receives an input value of 0.53 (=0.5+0.03), and the cell E7 corresponding to the position Z15 of the transport vehicle 4C traveling on the first straight route Ws1 receives an input value of 0.63 (=0.5+0.13).

The transport vehicle 4D is a transport vehicle 4 traveling on the first curved route Wc1 and is at the position Zm3 on the first connecting rail 28. The transport vehicle 4D is traveling and thus has no waiting time. Thus, the cell A1 that is one of the cells A1 to D4 corresponding to the position Zm3 receives an input value of 0.5.

The transport vehicle 4E is a transport vehicle 4 to travel on the second straight route Ws2 and is at the position Z25 on the second straight rail 27. The transport vehicle 4E has a waiting time of 50 seconds at the time point. In this example, a value of 0.5 is added for the waiting time of 50 seconds. Thus, the cell H6 corresponding to the position Z25 of the transport vehicle 4E traveling on the second straight route Ws2 receives an input value of 1 (=0.5+0.5).

The transport vehicle 4F is a transport vehicle 4 traveling on the second curved route Wc2 and is at the position Zm4 on the second connecting rail 29. The transport vehicle 4F is traveling and thus has no waiting time. Thus, the cell L12 that is one of the cells L12 to 19 corresponding to the position Zm4 receives an input value of 0.5.

The transport vehicle 4G is a transport vehicle 4 traveling on the second straight route Ws2 and is at the position Z28 on the second straight rail 27. The transport vehicle 4G is traveling and thus has no waiting time. Thus, the cell G3 corresponding to the position Z28 of the transport vehicle 4G traveling on the second straight route Ws2 receives an input value of 0.5.

In the present embodiment, the travel patterns to be evaluated are limited to the first to fourth travel patterns as described above. Thus, each of the cells F6 to G7 respectively corresponding to the travelability a1 to a4 of the travel patterns to be evaluated receives an input value of 0.8 or 0.2 as appropriate for the corresponding travel pattern to be evaluated.

When the first travel pattern is evaluated, the cells F6 and F7 respectively corresponding to the travelability a1 and a2 receive the input value of 0.8, and the cells G7 and G6 respectively corresponding to the travelability a3 and a4 receive the input value of 0.2.

When the second travel pattern is evaluated, the cells F6 and G7 respectively corresponding to the travelability a1 and a3 receive the input value of 0.8, and the cells F7 and G6 respectively corresponding to the travelability a2 and a4 receive the input value of 0.2.

When the third travel pattern is evaluated, the cells F7 and G6 respectively corresponding to the travelability a2 and a4 receive the input value of 0.8, and the cells F6 and G7 respectively corresponding to the travelability a1 and a3 receive the input value of 0.2.

When the fourth travel pattern is evaluated, the cells G7 and G6 respectively corresponding to the travelability a3 and a4 receive the input value of 0.8, and the cells F6 and F7 respectively corresponding to the travelability a1 and a2 receive the input value of 0.2.

The evaluation processor 54 outputs an evaluation value based on the input base data described above and the evaluation criterion ST obtained through learning. The evaluation criterion ST is defined by a function that returns a value by performing a computation using each of the input numerical values. The evaluation criterion ST is defined to allow, based on the results of learning the relationship among the state information F, the travel pattern, and the travel time period in the past, a higher evaluation value for a less average of travel time periods of all the transport vehicles 4 in the control area A. The evaluation values are calculated based on such an evaluation criterion ST, allowing selection of a travel pattern having a high evaluation value, and thus increasing the subsequent transport efficiency.

In the present embodiment, the evaluation criterion ST is defined to allow a higher evaluation value for a smaller variance in travel time periods of all the transport vehicles 4 in the control area A. In other words, the evaluation criterion ST is defined to allow a higher evaluation value for a less average of travel time periods and a smaller variance in travel time periods of all the transport vehicles 4 in the control area A. The evaluation values are calculated based on such an evaluation criterion ST, allowing selection of a travel pattern having a high evaluation value, and thus increasing the subsequent transport efficiency and decreasing travel time fluctuations.

In these cases, the transport efficiency may be increased by temporarily maximizing the transport efficiency at the time point.

In the present embodiment, to improve the long-term transport efficiency, the evaluation criterion ST is defined to include an action value function for calculating an expected value of a cumulative reward when a reward is greater for the travel time periods being shorter. In the present embodiment, each evaluation criterion ST is defined to include an action value function for calculating an expected value of the cumulative reward when a reward is greater for the travel time periods being shorter and a smaller variance in the travel time periods. Such an action value function can be derived through reinforcement learning using, for example, a deep Q-network (DQN).

When each evaluation criterion ST is defined to include the action value function as described above, the evaluation processor 54 outputs, as the evaluation value, the value of the action value function (Q-value) for each of the multiple travel patterns determined using the state information F that is input at the time point. The evaluation criterion ST defined to include the action value function can be used to calculate the evaluation values for continuously selecting a travel pattern having a high evaluation value, thus not temporarily but continuously shortening the average travel time of the multiple transport vehicles 4. This can greatly increase the long-term transport efficiency.

The evaluation processor 54 outputs the evaluation value at predetermined time intervals.

The traffic controller 55 compares the evaluation values (the values of action value function in the present embodiment) that are each output for the respective travel patterns to be evaluated to perform traffic control of the multiple transport vehicles 4 in the control area A based on the travel pattern having the highest evaluation value.

When the evaluation value for the first travel pattern is the highest, the traffic controller 55 controls the target transport vehicles 4 to sequentially travel on the first straight route Ws1 and the first curved route Wc1. When the evaluation value for the second travel pattern is the highest, the traffic controller 55 controls the target transport vehicles 4 to sequentially travel on the first curved route Wc1 and the second curved route Wc2. When the evaluation value for the third travel pattern is the highest, the traffic controller 55 controls the target transport vehicles 4 to sequentially travel on the first straight route Ws1 and the second straight route Ws2. When the evaluation value for the fourth travel pattern is the highest, the traffic controller 55 controls the target transport vehicles 4 to sequentially travel on the second straight route Ws2 and the second curved route Wc2.

The traffic controller 55 performs traffic control at predetermined time intervals.

In this manner, the traffic control of the multiple transport vehicles 4 in the control area A based on the travel pattern having the highest evaluation value (the maximum value of the action value function in the present embodiment) can greatly increase the long-term transport efficiency.

### Other Embodiments

(1) In the above embodiment, specific example values are input as the base data used to calculate the evaluation value. However, the numerical values corresponding to various events, such as +0.5 for a transport vehicle 4 at the corresponding position, +f (waiting time) for a waiting time, 0.8 for travel permission, and 0.2 for travel prohibition, are mere examples. These values may be set as appropriate for the common specifications of the transport facility 1 or for particular conditions of the corresponding transport facility 1.

(2) In the above embodiment, for the base data that is input to calculate the evaluation value, the value of +f (waiting time) for the waiting time is discretely determined based on each waiting time. However, the structure is not limited to this example. The value of +f may be linearly determined based on the waiting times. In some embodiments, a numerical value may not be added independently of the waiting time. In this case, the state information F does not include information indicating the degree of waiting time period for each transport vehicle 4 in the control area A.

(3) In the above embodiment, the waiting time is defined as the stop duration at a specific position. However, the structure is not limited to this example. The stop duration may be defined as, for example, the time taken by a transport vehicle to pass the first exit position Po1 or the second exit position Po2 after stopping in the control area A for the first time. The waiting time can also be defined in various other manners.

(4) In the above embodiment, the state information F includes information indicating the positional relationship among the multiple transport vehicles 4 in the control area A, the degree of waiting time period for each transport vehicle 4 in the control area A, and the travel direction (the path to be traveled) of each transport vehicle 4. However, the structure is not limited to this example. The state information F may simply include information indicating the positional relationship among the multiple transport vehicles 4 in the control area A without including information indicating the degree of waiting time period or the travel direction. In some embodiments, the state information F may further include other information. Other information may include, for example, speed information about each transport vehicle 4 and orientational information about each transport vehicle 4 at the time point. Other information may also include, for example, information indicating whether travel permission is received or information about a transportation task (information about a package to be transported or a priority level of the task).

(5) In the above embodiment, the evaluation criterion ST obtained through learning is defined to allow a higher evaluation value for a less average of travel time periods of all the transport vehicles 4 in the control area A. However, the structure is not limited to this example. The evaluation value may be calculated based on travel speed, stop duration, a stop count, and other items that are associated with each transport vehicle 4 and affect the travel time, in addition to the average of travel time periods of all the transport vehicles 4.

(6) In the above embodiment, the state information obtainer 52 tracks the portion between the first entry position Pi1 and the first exit position Po1 on the first straight rail 26 as a single position (position Zm1). However, the structure is not limited to this example. The state information obtainer 52 may also track the portion between the first entry position Pi1 and the first exit position Po1 on the first straight rail 26 as segmented positions (positions Zm11, Zm12, . . . ). Similarly, the state information obtainer 52 may track the portion between the second entry position Pi2 and the second exit position Po2 on the second straight rail 27 as segmented positions (positions Zm21, Zm22, . . . ). This improves the accuracy of the state information F (specifically, information indicating the positional relationship among the multiple transport vehicles 4), allowing more accurate calculation of evaluation values.

(7) In the above embodiment, the state information obtainer 52 tracks the first connecting rail 28 as a single position (position Zm3). However, the structure is not limited to this example. The state information obtainer 52 may also track the first connecting rail 28 as segmented positions (positions Zm31, Zm32, . . . ). Similarly, the state information obtainer 52 may track the second connecting rail 29 as segmented positions (positions Zm41, Zm42, . . . ). This improves the accuracy of the state information F (specifically, information indicating the positional relationship among the multiple transport vehicles 4), allowing more accurate calculation of evaluation values.

(8) In the above embodiment, the host control device 50 includes the travel time measurer 53 that measures the travel time for each transport vehicle 4. However, the structure is not limited to this example. Each terminal control device 59 on the corresponding transport vehicle 4 may include the travel time measurer 53 that transmits the measurement results to the host control device 50.

(9) In the above embodiment, the control system 5 includes the host control device 50 and the terminal control devices 59 that are mounted on the respective transport vehicles 4 to allow communication with the host control device 50. However, the structure is not limited to this example. The control system 5 may include, for example, the terminal control devices 59 mounted on the respective transport vehicles 4 to allow mutual communication.

(10) In the structure mainly described in the above embodiment, the transport vehicles 4 are ceiling-hung transport vehicles. However, the structure is not limited to this example. The transport vehicles 4 may be, for example, tracked carriages or automated guided vehicles (AGV). In the latter case, the travelable path 2 may be defined by, for example, magnetic tape disposed on the floor surface.

(11) The structures described in the above embodiments (including the above and other embodiments; the same applies hereafter) may be combined with the structures described in the other embodiments unless any contradiction arises. The embodiments described herein are merely illustrative in all aspects and may be modified as appropriate without departing from the spirit and scope of the present disclosure.

### Overview of Embodiments

The transport facility according to one or more embodiments of the present disclosure may have the structure overviewed below.

A transport facility includes a predefined travelable path, a plurality of transport vehicles that travel along the travelable path, and a control system that controls the plurality of transport vehicles. The travelable path includes at least one junction at which a plurality of paths merge. The control system includes a state information obtainer, an evaluation processor, and a traffic controller. The state information obtainer obtains, when the plurality of transport vehicles are in a control area including the at least one junction, state information including information indicating a positional relationship among the plurality of transport vehicles in the control area. The evaluation processor defines a plurality of travel patterns based on combinations of permission and prohibition for each of the plurality of transport vehicles to travel on each of the plurality of paths connected to the at least one junction in the control area, and outputs, using the state information as input, an evaluation value for each of the plurality of travel patterns based on an evaluation criterion obtained through learning. The traffic controller performs traffic control of the plurality of transport vehicles in the control area based on a travel pattern having a highest evaluation value among the plurality of travel patterns. The evaluation criterion is defined to allow, based on results of learning a relationship among the state information, the travel pattern, and a travel time period in a past, a higher evaluation value for a less average of travel time periods of all the plurality of transport vehicles in the control area. The travel time period is a time period taken by a corresponding transport vehicle of the plurality of transport vehicles to pass the at least one junction after entering the control area.

In this structure, the evaluation criterion obtained through learning is defined to allow a higher evaluation value for a less average of travel time periods of all the transport vehicles in the control area including at least one junction. Using such an evaluation criterion, an evaluation value for each of the possible travel patterns is output to perform traffic control based on the travel pattern having the highest evaluation value. This increases the transport efficiency of all the transport vehicles traveling in the area including at least one junction.

In one aspect, the evaluation criterion may be further defined to allow a higher evaluation value for a smaller variance in the respective travel time periods of all transport vehicles in the control area.

In this structure, the evaluation criterion obtained through learning is defined to allow a higher evaluation value for a less average of travel time periods and a smaller variance in travel time periods of all the transport vehicles in the control area. The traffic control performed based on such an evaluation criterion can increase the overall transport efficiency and decrease the travel time fluctuations in the transport vehicles traveling in the area including at least one junction.

In one aspect, the state information may further include information indicating a degree of waiting time periods for each of the plurality of transport vehicles in the control area.

In this structure, the evaluation criterion is defined based on the degree of waiting time periods for each transport vehicle in addition to the positional relationship among the multiple transport vehicles in the control area. This structure is thus more likely to reduce the travel time fluctuations in the multiple transport vehicles traveling in the area including at least one junction.

In one aspect, the evaluation criterion may be defined to include an action value function for calculating an expected value of a cumulative reward when a reward is greater for the travel time periods being shorter. The evaluation processor may output, as the evaluation value, a value of the action value function for each of the plurality of travel patterns determined using the state information as input at a time point.

In this structure, the traffic control is repeatedly performed, in constantly changing transport conditions, based on the travel pattern having the highest evaluation value (the highest action value function) at each time point to increase the overall and long-term transport efficiency of the transport vehicles traveling in the area including at least one junction.

The transport facility according to one or more embodiments of the present disclosure produces at least one of the effects described above.

### REFERENCE SIGNS LIST

1 transport facility
2 travelable path
4 transport vehicle
5 control system
52 state information obtainer
54 evaluation processor
55 traffic controller
J junction
A control area
ST evaluation criterion
F state information

What is claimed is:

1. A transport facility, comprising:
a predefined travelable path;
a plurality of transport vehicles configured to travel along the travelable path; and
a control system configured to control the plurality of transport vehicles, and
wherein:
the travelable path includes at least one junction at which a plurality of paths merge,
the control system comprises:
a state information obtainer configured to obtain, when the plurality of transport vehicles are in a control area comprising the at least one junction, state information comprising information indicating a positional relationship among the plurality of transport vehicles in the control area,
an evaluation processor configured to define a plurality of travel patterns based on combinations of permission and prohibition for each of the plurality of transport vehicles to travel on each of the plurality of paths connected to the at least one junction in the control area, and output, using the state information as input, an evaluation value for each of the plurality of travel patterns based on an evaluation criterion obtained through learning, and
a traffic controller configured to perform traffic control of the plurality of transport vehicles in the control area based on a travel pattern having a highest evaluation value among the plurality of travel patterns,
the evaluation criterion is defined to allow, based on results of learning a relationship among the state information, the travel pattern, and a travel time period in a past, a higher evaluation value for a less average of travel time periods of all the plurality of transport vehicles in the control area, and
the travel time period is a time period taken by a corresponding transport vehicle of the plurality of transport vehicles to pass the at least one junction after entering the control area.

2. The transport facility according to claim 1, wherein:
the evaluation criterion is further defined to allow a higher evaluation value for a smaller variance in the respective travel time periods of all transport vehicles in the control area.

3. The transport facility according to claim 1, wherein:
the state information further comprises information indicating a degree of waiting time period for each of the plurality of transport vehicles in the control area.

4. The transport facility according to claim 1, wherein:
the evaluation criterion is defined to include an action value function for calculating an expected value of a cumulative reward when a reward is greater for the travel time periods being shorter, and
the evaluation processor outputs, as the evaluation value, a value of the action value function for each of the plurality of travel patterns determined using the state information as input at a time point.
